(19) United States
(12) Patent Application Publication
(10) Pub. No.: US 2012/0152303 A1
(43) Pub. Date: Jun. 21, 2012

(54) Organic Solar Cell or Photodetector Having Improved Absorption

(75) Inventors: Jan Meiss, Dresden (DE); Markus Hummert, Dresden (DE); Rico Schueppel, Dresden (DE); Moritz Riede, Dresden (DE); Annette Petrich, Dresden (DE); Karl Leo, Dresden (DE)

(73) Assignee: TECHNISCHE UNIVERSITAET DRESDEN, Dresden (DE)

(21) Appl. No.: 13/320,978

(22) PCT Filed: May 17, 2010
(86) PCT No.: PCT/DE2010/000536

§ 371 Date: Mar. 9, 2012

(30) Foreign Application Priority Data
May 18, 2009 (DE) 10 2009 022 408.4

(51) Int. Cl. H01L 31/042; H01L 51/46; H01L 31/04; B32B 15/04; B32B 9/04; B32B 9/00; B32B 3/02; B32B 17/06; B32B 18/00; B32B 3/10; B32B 5/16; B32B 5/02; C07C 13/62; B82Y 20/00; B82Y 30/00

(52) U.S. Cl. 136/244; 585/27; 257/40; 136/255; 428/457; 428/688; 428/411.1; 428/76; 428/446; 428/702; 428/195.1; 428/328; 428/323; 428/426; 428/221; 257/E51.026; 977/773

(57) ABSTRACT

The invention relates to an organic photoactive component, especially a solar cell or a photodetector, built up from a plurality of layers, wherein at least one of the layers comprises at least one di-indeno[1,2,3-cd:1′,2′,3′-lm]perylene compound of the general formula in Illustration 1, wherein each R¹-R¹⁶ is independently selected from hydrogen, halogen, unsubstituted or substituted, saturated or unsaturated C₁-C₂₀-alkyl, C₁-C₂₀-heteroalkyl, C₆-C₂₀-aryl, C₆-C₂₀-heteroaryl, saturated or unsaturated carbocycle or heterocycle, which may be the same or different, wherein two adjacent radicals R¹-R¹⁶ may also be part of a further saturated or unsaturated, carbocyclic or heterocyclic ring, wherein the ring may comprise C, N, O, S, Si and Se, and the use of the said component.

### FIELD OF THE INVENTION

The invention relates to a photoactive component, especially an organic solar cell or a photodetector, with a layer arrangement comprising an electrode and a counter-electrode and a sequence of organic layers arranged between the electrode and the counter-electrode.

### BACKGROUND OF THE INVENTION

Since the demonstration of the first efficient organic solar cell with an efficiency in the percentage range by Tang et al. 1986 (C. W. Tang et al., Appl. Phys. Lett. 48, 183 (1986)), organic materials have been investigated intensively for a variety of electronic and optoelectronic components. Organic solar cells consist of a series of thin layers, which are typically between 1 nm and 1 μm thick, of organic materials, which are vapour-deposited in a vacuum or applied from a solution. The electric contacts are as a rule provided by transparent, semitransparent or non-transparent layers of metal and/or transparent conductive oxides (TCOs) and/or conductive polymers.

The advantage of such organic-based components over the conventional inorganic-based components, e.g. semiconductors such as silicon or gallium arsenide, is the optical absorption coefficients, which can sometimes be extremely high and reach as much as 3×105 cm−1, so that the possibility is created of producing very thin solar cells with little material and energy input. Other technological aspects are the low costs, the possibility of producing flexible large-area components on plastic films, and the virtually unlimited possible variations available in organic chemistry.

In the following, three key points will be explained, which constitute central technical problems in the development and successful economic exploitation.

A solar cell converts the energy of light into electrical energy. In contrast to inorganic solar cells, free charge carriers are not created directly by the light in the case of organic solar cells, but instead bound Frenkel excitons first form, which are electrically neutral excitation states in the form of bound electron-hole pairs. These excitons can only be separated by very powerful electric fields or at suitable interfaces. Sufficiently powerful fields are not available in organic solar cells, so that all the promising concepts for organic solar cells are based on the separation of excitons at photoactive interfaces (Organic Donor-Acceptor Interface—C. W. Tang, Applied Physics Letters, 48 (2), 183-185 (1986)) or Inorganic Semiconductor Interface (cf. B. O'Regan et al., Nature 353, 737 (1991)). For this, it is necessary for excitons generated in the bulk of the organic material to be able to diffuse to this photoactive interface.

The low-recombination diffusion of excitons to the active interface therefore plays a critical role in the case of organic solar cells. In order to make a contribution to photoelectric current, the exciton diffusion length in a good organic solar cell must therefore be at least in the same range as the typical penetration depth of light so that the greater part of the light can be exploited. Organic crystals or thin films which are perfect in terms of their structure and chemical purity certainly satisfy this criterion. For large-scale applications, however, it is not possible to use monocrystalline organic materials, and the production of multiple layers with sufficient structural perfection is still very difficult, even today.

Instead of increasing the exciton diffusion length, it is also possible to reduce the mean distance from the closest interface. Document WO 00/33396 proposes the creation of an interpenetrating network: a layer contains a colloidally dissolved substance, which is distributed in such a way that a network forms via which the charge carriers can flow (percolation mechanism). In a network of this kind, the task of light absorption is performed either by only one of the components or by both.

The advantage of a mixed layer of this kind is that the excitons produced only have to travel a very short distance before they reach a domain boundary, where they are separated. The electrons and holes are transported away separately in the dissolved substance or in the rest of the layer. Since the materials in the mixed layer are in contact with one another everywhere, it is decisive with this concept that the separated charges should have a long life on the material concerned and that closed percolation paths are available from every location for both charge carrier locations to the respective contact. With this approach, it was possible to achieve efficiencies of 2.5% for polymer-based solar cells produced by wet-chemical means (C. J. Brabec et al., Advanced Functional Material 11, 15 (2001)), while polymer-based tandem cells already have an efficiency of more than 6% (J. Y. Kim et al., Science 13, 222-225 (2007)). Other known approaches for achieving or improving the properties of organic solar cells are listed below:
One contact metal has a large work function and the other a small one, so that a Schottky barrier is formed with the organic layer (U.S. Pat. No. 4,127,738).
The active layer consists of an organic semiconductor in a gel or binder (U.S. Pat. No. 3,844,843, U.S. Pat. No. 3,900,945, U.S. Pat. No. 4,175,981 and U.S. Pat. No. 4,175,982).
Creation of a transport layer containing small particles with a size of about 0.01 to 50 μm, which see to the transport of charge carriers (U.S. Pat. No. 5,965,063).
A layer contains two or more kinds of organic pigments, which possess different spectral characteristics (JP 04024970).
One layer contains a pigment, which produces the charge carrier, and in addition a material which transport the charge carrier away (JP 07142751).
Polymer-based solar cells which contain carbon particles as electron acceptors (U.S. Pat. No. 5,986,206)
Doping the above-mentioned mixed systems to improve the transport properties in multilayer solar cells (cf. DE 102 09 789)
Arranging individual solar cells on top of one another, so that a tandem cell is formed (U.S. Pat. No. 4,461,922; U.S. Pat. No. 6,198,091; U.S. Pat. No. 6,198,092).
Tandem cells can be further improved by using p-i-n structures with doped transport layers with a wide bandgap (DE 103 13 232).

As described above, an inherent difficulty with organic solar cells is the fact that the exciton diffusion lengths in the organic absorber materials are in ranges from approx. 10 nm to 40 nm. So that the excitons do not recombine in the absorber layer and the energy in the context of the solar cell is lost, the layer thicknesses of the absorber should be in the same range as the exciton diffusion length.

This strict limitation of the absorber layer thicknesses to size ranges which as a rule are well below 60 nm also always limits the absorption (and hence also the photoelectric current and efficiency) in an organic solar cell. Even the above-mentioned interpenetrating networks can only partially compensate for this problem. It is therefore decisive that absorber materials should be found which either alone or in a combination of more than one material should optimally exploit a broad spectral range of visible light and have powerful absorption characteristics despite the small maximum layer thicknesses.

At present, standard materials used in organic solar cells in research and development are “metal phthalocyanines” (such as copper phthalocyanine, CuPc, or zinc phthalocyanine, ZnPc) and fullerenes (such as C60). Although these materials are known, easy to handle and easy to obtain, they alone will not offer a lasting solution; the reason for this is that, on the one hand, they do not absorb sufficiently strongly and. on the other hand, are only able to exploit a narrow range of the sunlight available. According to the present state of the art, it is possible to absorb preferably in a wavelength range around 450 nm with C60; with ZnPc, it is possible to absorb in a wavelength range around 650-700 nm. A great part of the energy of sunlight with wavelengths between 450 and 650 nm thus remains unused (M. Riede et al., Nanotechnology 19, 424001 (2008)). Furthermore, not all the light can be absorbed in the absorbing ranges, because the thin layers do not absorb sufficiently strongly.

To sum up, it can thus be said that when today's standard materials are used,
1.) a broad wavelength range (450-650 nm, around the green range of the spectrum) remains unused, which reduces the photoelectric current
2.) the remainder of the spectrum is relatively poorly used
3.) precisely a range of very intense light with a high level of photon energy (450-600 nm lost, which limits the photovoltage.

All in all, it can therefore be said that it will not be possible to compensate for the problem of the limited separation of excitons because of the short exciton diffusion length with the present absorbers and that new materials will be necessary.

Another major field of problems in research and development regarding organic solar cells is the subject of suitable energy levels. If the charge carriers produced are to be transported away efficiently, there must be no energy barriers between the absorber materials and the electric contacts of a solar cell. With the p-i-n architecture, or with doped organic layers, it is possible to a certain extent to ensure that energy barriers are reduced and that the electrons and holes generated are transported away well (K. Walzer et al., Chemical Reviews 107(4), 1233-1271 (2007); C. Falkenberg et al., Journal of Applied Physics 104, 034506 (2008); S. Pfützner et al., Proceedings of SPIE 6999, 69991M (2008); C. Uhrich et al., Journal of Applied Physics 104, 043107 (2008); J. Drechsel et al., Applied Physics Letters 86, 244102 (2005)). This method is well-known by now and has been tried and tested for the materials ZnPc and C60. Since, however, as described above, ZnPc and C60 do not have sufficiently good properties, it can be said in this case too that there is an urgent need for other materials, which not only possess good absorber properties, but also need to have suitable energy levels so that, in combination with doped transport layers, high open-circuit voltages and filling factors are ensured.

A key aspect in this connection is the production of tandem, triple or multiple cells in general, consisting of a stack of a plurality of solar cells, so that the multiple cell as a whole can absorb in a broad spectral range thanks to different absorber materials, each of which only absorb a specific part of the spectrum. In this way, it is possible to a certain extent to circumvent the problem of the only limited exciton diffusion length, since a multiple solar cell can be regarded as a layered stack of plural solar cells (so-called subcells), in which a plurality of absorber layers can co-operate. In this way, considerably higher efficiencies than with single cells can be achieved. It is, however, important in this connection, if a plurality of materials are used which have similar absorber characteristics (i.e. they absorb at similar wavelengths), that the layers also take photons away from one another and limit one another as a result of the fact that photons absorbed by one subcell are no longer available to other subcells. This problem can only be avoided if different absorbers are used which are complementary to one another and absorb in different wavelength ranges. The tandem/multiple-cell technology thus also makes it clear once again that a broad spectral range is necessary for efficient solar cells. Tandem/multiple cells made from the materials C60 and ZnPc are therefore not a solution.

In order to be able to satisfy the above-mentioned requirements regarding exciton diffusion length, energy levels and multiple cells, it is therefore urgently necessary to find new absorber materials which can fill the absorption gap between C60 and ZnPc, which have a strong absorption and have favourable energy levels (Highest Occupied Molecular Orbital [HOMO], Lowest Unoccupied Molecular Orbital [LUMO]). With the present state of the art, it is not possible to achieve sufficient efficiencies, which would be necessary in order to satisfy the economic and technological requirements of organic photovoltaic systems.

The present state of the art in the case of absorber molecules in organic photovoltaic systems for filling the gap between C60 and ZnPc is the class of substances of dicyanovinyl oligothiophenes (DCVTs) (K. Schulze et al., Advanced Material 18, 2872 (2006)), shown in FIG. 2, with R=alkyl or H. The synthesis of DCVTs is, however, complex and involves a number of problems. In a number of repeating steps, active positions of the thiophene/oligothiophene are protected or functionalised, in the process of which the chains is in each case extended by a thiophene unit. Specifically, the necessary purification of the compounds by sublimation is problematic, because the dicyanovinyl moiety reacts sensitively to the influence of the higher temperature during sublimation. In the process, fragmentation of the molecule occurs, with the loss of CH2═C(CN)2. Hence, while DCVTs are a possible solution from the scientific point of view on a laboratory scale, this class of materials is nevertheless not suitable for economic purposes (mass production).

Employees at Sanyo reported on tetraphenyl dibenzoperiflanthene as a donor material in organic solar cells (Fujishima et al., Solar Energy Material and Solar Cells 93, 1029 (2009); identical to Kanno et al., Proc. PVSEC-17). They succeeded in creating a simple solar cell consisting of the organic materials tetraphenyl dibenzoperiflanthene, C60 and 2,9-dimethyl-4,7-diphenyl-1,10-phenantroline. Thanks to the strong absorption of tetraphenyl dibenzoperiflanthene, Fujishima and Kanno achieved an efficiency of 3.56% for 0.033 cm² and 2.58% for 1.60 cm², though it is not clearly stated whether the data were already checked for a spectral mismatch. Despite this result, it is nevertheless clear that with the system chosen by Fujishima and Kanno, no further efficiency increase can be expected: ultimately, the absorption of the C60-tetraphenyl dibenzoperiflanthene compound limits the photoelectric current and photovoltage; it would be necessary to use doped dedicated charge carrier transporters in order to arrive at higher filling factors. Single cells with tetraphenyl dibenzoperiflanthene therefore do not provide a solution for the above-mentioned requirements.

The problem of the invention is to use a suitable thermally stable material, which is easy to synthesise, in order to satisfy the requirements described above with regard to achieving greater efficiencies in such a way that
a broad spectral range is exploited,
use in tandem cells or multiple solar cells is possible,
by using suitable transport materials in connection with the solar cell together with a suitable absorber material, the filling factor and voltage can be optimised without losses.

### BRIEF SUMMARY

This problem is solved by an organic photoactive component in accordance with claim 1 and the use of such components in accordance with claims 31 and 32. Preferred embodiments can be found in the dependent claims.

This problem is solved in accordance with the invention by an organic photoactive component, especially a solar cell or photodetector composed of a plurality of layers, wherein at least one of the layers comprises at least one di-indeno[1,2,3-cd:1′,2′,3′-lm]perylene compound of the general formula

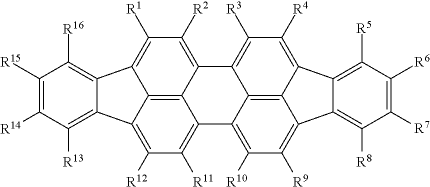

wherein each R¹-R¹⁶ is independently selected from hydrogen, halogen, unsubstituted or substituted, saturated or unsaturated C₁-C₂₀-alkyl, C₁-C₂₀-heteroalkyl, C₆-C₂₀-aryl, C₆-C₂₀-heteroaryl, saturated or unsaturated carbocycle or heterocycle, which may be the same or different. In addition, two adjacent radicals R¹-R¹⁶ may be part of a further saturated or unsaturated, carbocyclic or heterocyclic ring or chain, wherein the ring or chain may comprise C, N, O, S, Si and Se. In the following, a material corresponding to the above description will be abbreviated to “di-indenoperylene compound”.

### DETAILED DESCRIPTION

Advantageous embodiments are the subject matter of dependent claims. One subject matter of a further invention in this context is that the di-indeno[1,2,3-cd:1′,2′,3′-lm]perylene compounds mentioned are particularly advantageously combined with doped transport layers for electrons and holes. These surprisingly result in extremely high filling factors, which are not otherwise reported in organic solar cells.

A further, dependent invention is tandem solar cells with the above-mentioned di-indeno[1,2,3-cd:1′,2′,3′-lm]perylene compounds. It has surprisingly been found in this context that with the appropriate substitution, spectral absorption can be achieved, so that together with the known class of substances of phthalocyanines, there is no major overlap, and the two subcells do not in each case reduce the current of the other cells.

In accordance with the invention, the di-indenoperylene compound is used as a light-absorbing material in photoactive components, especially organic solar cells. The optical density of dibenzoperiflanthene, for example, as shown in FIG. 3, indicates good absorption centred around the green range of the visible spectrum.

Other derivatives can be synthesised in a targeted manner in this way, such that their absorption is adapted precisely to the respective requirements. Specific examples here are (in the order from higher to lower wavelengths) 1,4,9,12-tetraphenyl-di-indeno[cd:lm]perylene, 2,3,10,11-tertaethyl-1,4,9,12-tetraphenyl-di-indeno[cd:lm]perylene and 2,3,10,11-tertabutyl-1,4,9,12-tetraphenyl-di-indeno[cd:lm]perylene. These derivatives absorb at even lower wavelengths in each case (shifted even further into the blue), as is shown further down in FIG. 3, so that the overlap to ZnPc can be kept to a minimum.

Preferred applications of the invention are tandem, triple or multiple solar cells in general, in which the molecule is used as an absorber material. It is advantageous in the invention to provide further organic layers in order to optimise the energy levels between the absorber layer and the electric contact of the solar cell in a targeted way, so that with an efficient charge transport, high photoelectric currents, photovoltages and filling factors can be achieved. Advantageous applications of the invention therefore comprise the combination of the absorber materials with doped, non-absorbing or doped, absorbing organic materials. Advantageous applications of the invention in the use in tandem cells comprise the use of heavily doped layers as conversion contacts.

Examples of materials for the electric base contact are metals (for example, but not limited to: aluminium or silver), conductive polymers (for example, but not limited to: polyethylene dioxythiophene):poly(styrene sulphonate) [PEDOT:PSS]) or transparent conductive oxides (for example, but not limited to: aluminium-doped zinc oxide, tin-doped indium oxide, fluorine-doped tin oxide) or combinations of metal, conductive polymer or transparent conductive oxide.

Preferred examples of the materials conducting positive charges are 4,4′,4″-tris(1-naphthylphenylamino)-triphenyl amine (TNATA), N,N′-di(naphthalene-1-yl)-N,N′-diphenyl benzidine (alpha-NPD), 9,9-bis[4-(N,N-bis-biphenyl-4-yl-amino)phenyl]-9H-fluorene (BPAPF), 4,4′-bis-(N,N-diphenylamino)-quaterphenyl (4P-TPD), N,N′-diphenyl-N,N′-bis(4′-(N,N-bis(naphth-1-yl)-amino)-biphenyl-4-yl)-benzidine (Di-NPB), N,N,N′,N′-tetrakis(4-methoxyphenyl)-benzidine (MeO-TPD). Materials conducting positive charges may also be referred to as hole transport materials, which can be used in a hole transport layer (HTL), see also FIG. 8, layer 2, and FIG. 10, layer 2.

An advantageous embodiment of the invention contains materials in the HTL which serve as dopants (acceptors) for the materials which preferably conduct positive charges (holes). An example of this is: 2,3,5,6-tetrafluoro-7,7,8,8-tetracyanoquinodimethane (F4-TCNQ).

Preferred examples of the materials conducting negative charges are 1,4,5,8-naphthalene-tetracarboxylic dianhydride (NTCDA) or Buckminster fullerenes (C60). An advantageous embodiment of the invention contains materials in the ETL which serve as dopants (donors) for the materials which preferably conduct negative charges (electrons). An example of this is: (N,N,N′,N′-tetramethylacridine-3,6-diamine) (AOB). Materials that conduct negative charges are also referred to as electron transport materials, which can be used in electron transport layers (ETL).

Examples of p-dopants are phthalocyanines, especially, but not limited to zinc phthalocyanines (ZnPc), copper phthalocyanines (CuPc); Buckminster fullerenes (e.g. C60 or C70); dicyanovinyl-oligothiophene derivative (DCVxT); chlorine-aluminium phthalocyanine (ClAlPc or also AlClPe); perylene derivatives. An advantageous embodiment of the invention contains materials in the active layer which serve as dopants for the light-absorbing materials.

Preferred examples of heavily doped materials are bathocuproine (BCP) or 4,7-diphenyl-1,10-phenanthroline (BPhen).

Preferred examples of materials which absorb photons are SiN, SiO2.

Preferred examples of materials which absorb photons and are applied in a mixed layer are N,N,N′,N′-tetrakis(4-methoxyphenyl)-benzidine (MeO-TPD) or tris(8-hydroxy-quinolinato)-aluminum (Alq3).

Preferred examples of materials for an exciton-blocker layer are TiO2 or SiO2.

The invention is based on the surprising finding, obtained by experiment, that di-indenoperylene compounds and derivatives are characterised not only by powerful absorption and thermal stability, but, in combination with heavily doped hole-transport materials, can keep energy harriers to a minimum, which leads to very high filling factors. In addition, experiments with tandem cells have shown that high photovoltages can be obtained when the spectral sensitivities of different materials are combined in a suitable way. A decisive factor here is that the materials should have suitable bandgaps in order to be able to optimise the absorption and energy levels.

It is thus clear that tetraphenyl dibenzoperiflanthene—incorporated in an appropriate material system—is a suitable absorber for constructing solar cells efficiently. This is due to the easy synthesis and
good processability
thermal stability and
simple, efficient synthesis.

Organic electronic devices, such as organic semiconductors, can be used to fabricate simple electronic components, e.g. resistors, diodes, field effect transistors, and also optoelectronic components like organic light emitting devices (e.g. organic light emitting diodes (OLED)), and many others. The industrial and economical significance of the organic semiconductors and their devices is reflected in the increased number of devices using organic semiconducting active layers and the increasing industry focus on the subject.

OLEDs are based on the principle of electroluminescence in which electron-hole pairs, so-called excitons, recombine under the emission of light. To this end the OLED is constructed in the form of a sandwich structure wherein at least one organic film is arranged as active material between two electrodes, positive and negative charge carriers are injected into the organic material and a charge transport takes place from holes or electrons to a recombination zone (light emitting layer) in the organic layer where a recombination of the charge carrier to singlet and/or triplet excitons occurs under the emission of light. The subsequent radiant recombination of excitons causes the emission of the visible useful light emitted by the light-emitting diode. In order that this light can leave the component at least one of the electrodes must be transparent. Typically, a transparent electrode consists of conductive oxides designated as TCOs (transparent conductive oxides), or a very thin metal electrode; however other materials can be used. The starting point in the manufacture of an OLED is a substrate on which the individual layers of the OLED are applied. If the electrode nearest to the substrate is transparent the component is designated as a “bottom-emitting OLED” and if the other electrode is designed to be transparent the component is designated as a “top-emitting OLED”. The layers of the OLEDs can comprise small molecules, polymers, or be hybrid.

The most reliable and efficient OLEDs are OLEDs comprising doped layers. By electrically doping hole transport layers with a suitable acceptor material (p-doping) or electron transport layers with a donor material (n-doping), respectively, the density of charge carriers in organic solids (and therefore the conductivity) can be increased substantially. Additionally, analogous to the experience with inorganic semiconductors, some applications can be anticipated which are precisely based on the use of p- and n-doped layers in a component and otherwise would be not conceivable. The use of doped charge-carrier transport layers (p-doping of the hole transport layer by admixture of acceptor-like molecules, n-doping of the electron transport layer by admixture of donor-like molecules) in organic light-emitting diodes is, e.g., described in US 2008/203406 and U.S. Pat. No. 5,093,698.

### BRIEF DESCRIPTION OF THE DRAWINGS

FIG. 1: shows the general structural formula of di-indeno[1,2,3-cd:1′,2′,3′-lm]perylene;

FIG. 2: shows a dicyanovinyl-oligothiophene compound;

FIG. 3: shows a graph of the absorption capacity of different perylene compounds;

FIG. 4: shows a reaction scheme for the production of the perylene compound used in accordance with the invention;

FIG. 5: shows the structural formula of 8,9-dibutyl-7,10-diphenyl fluoranthene;

FIG. 6: shows the structural formula of 2,3,10,11-tertabutyl-1,4,9,12-tetraphenyl-di-indeno[cd:lm]perylene;

FIG. 7: shows an example of a possible, archetypal layer structure of a single solar cell (cross-section), containing the substrate (0), an earthing electrode (1), an absorber (2) and a top electrode (3);

FIG. 8: shows an example of a possible, archetypal layer structure of a single solar cell (cross-section), with a substrate (0), earthing electrode (1), absorber (3) and top electrode (6), and additionally with functional layers as exciton blockers (EBL) (5), electron transporters (ETL) (4), hole transporters (HTL) (2);

FIG. 9: shows an example of a possible, archetypal layer structure of a multiple cell, in this case a tandem cell (cross-section), consisting of the substrate (0), an earthing electrode (1), an absorber of the subcell 1 (2), conversion contact (3), absorber from subcell 2 (4), top contact (5);

FIG. 10: shows an example of a possible, archetypal layer structure of a multiple cell, in this case a tandem cell (cross-section), consisting of the substrate (0), an earthing electrode (1), a hole transporter (HTL) (2), absorber of the subcell 1 (3), conversion contact (4), absorber of the subcell 2 (5), electron transporter (ETL) (6), exciton blacker (EBL) (7) and top electrode (8);

FIG. 11: shows an example of a layer structure of a single solar cell (cross-section) from embodiment 1; the layers are explained in more detail further down in worked embodiment 1.

FIG. 12: shows a current-voltage characteristic curve of a single solar cell from embodiment 1;

FIG. 13: shows an example of a layer structure of a single solar cell (cross-section) from embodiment 2; the layers are explained in more detail further down in worked embodiment 2.

FIG. 14: shows a current-voltage characteristic curve of a single solar cell from embodiment 2;

FIG. 15: shows an example of a layer structure of a multiple cell, in this case a tandem cell (cross-section) from embodiment 3; the layers are explained in more detail further down in worked embodiment 3.

FIG. 16: shows a current-voltage characteristic curve of a multiple cell, in this case a tandem cell, from embodiment 3;

FIG. 17: shows a current-voltage characteristic curve of a single solar cell from embodiment 4;

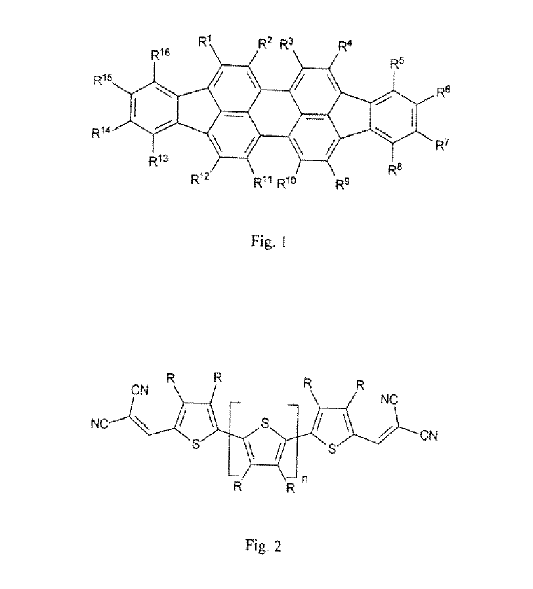

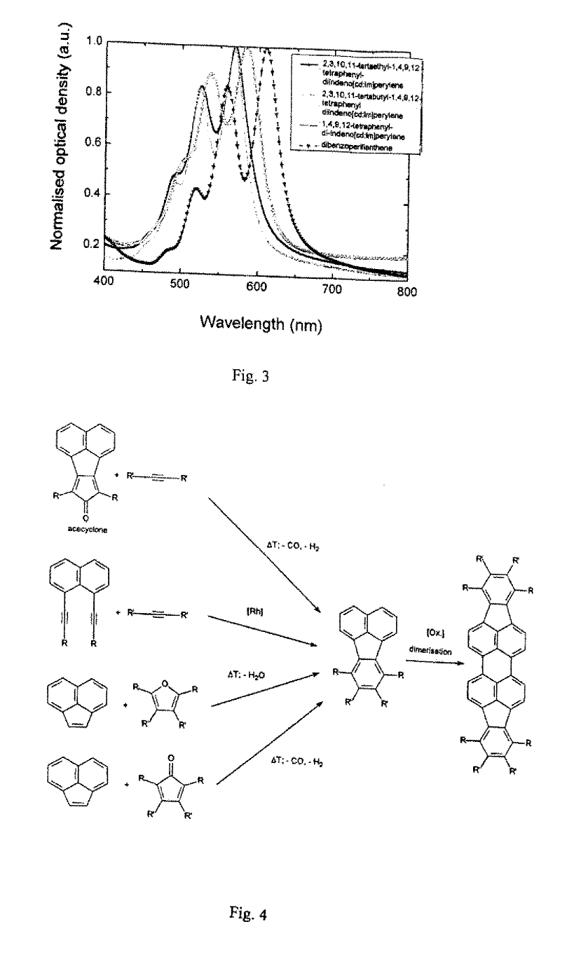

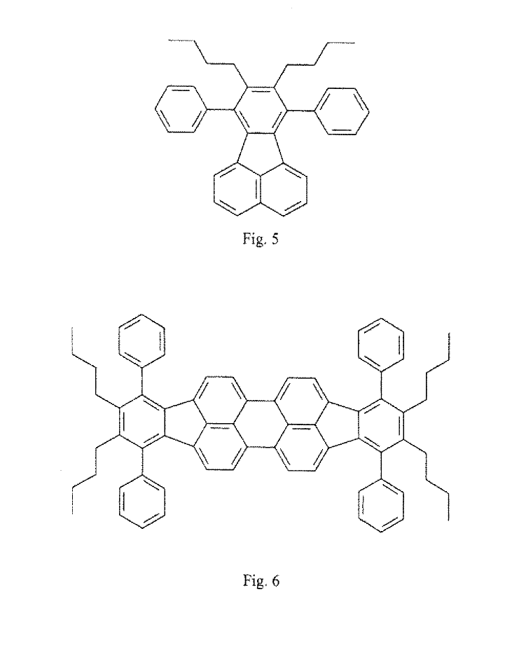

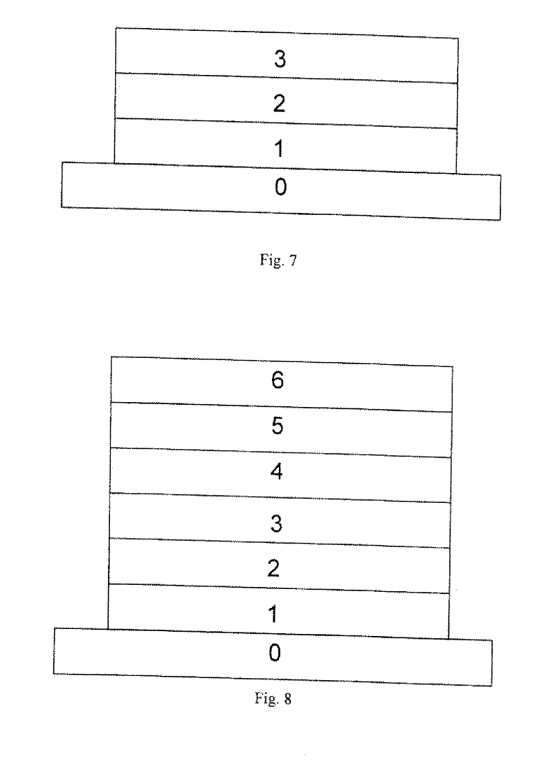

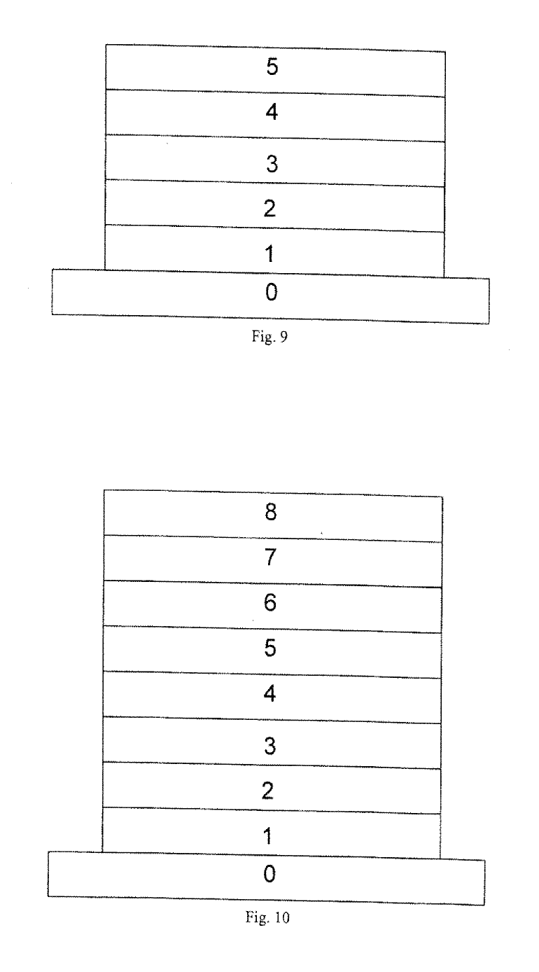

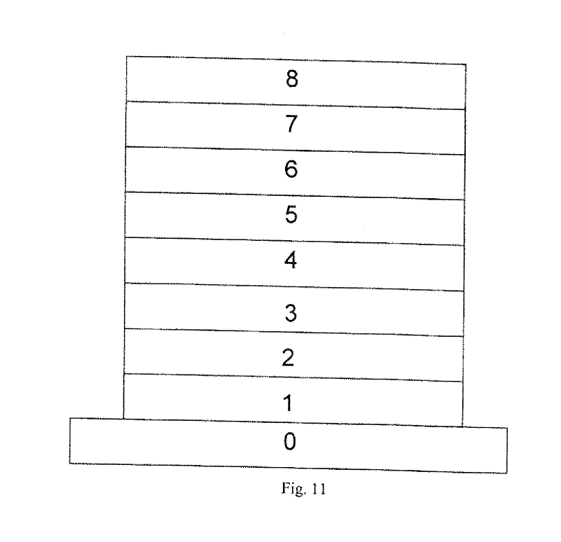

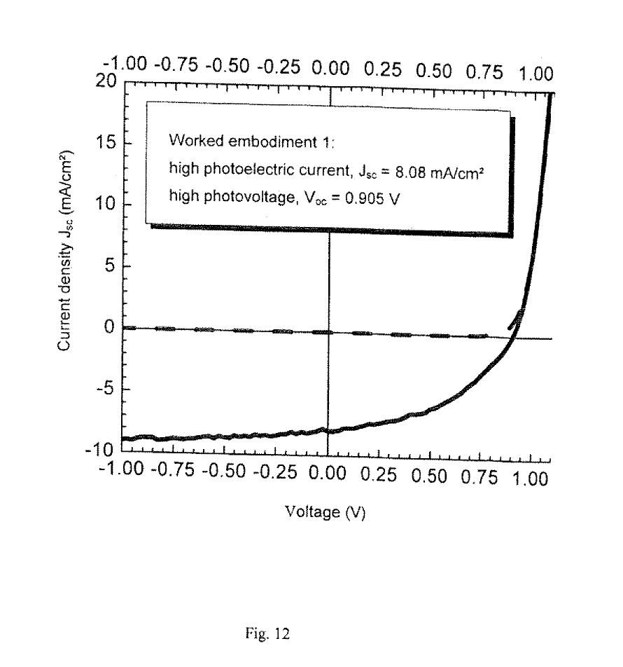

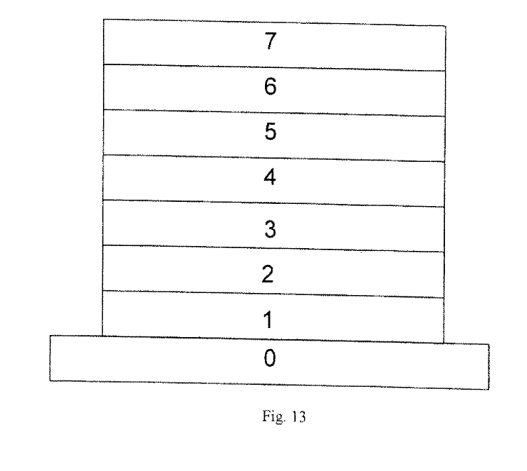

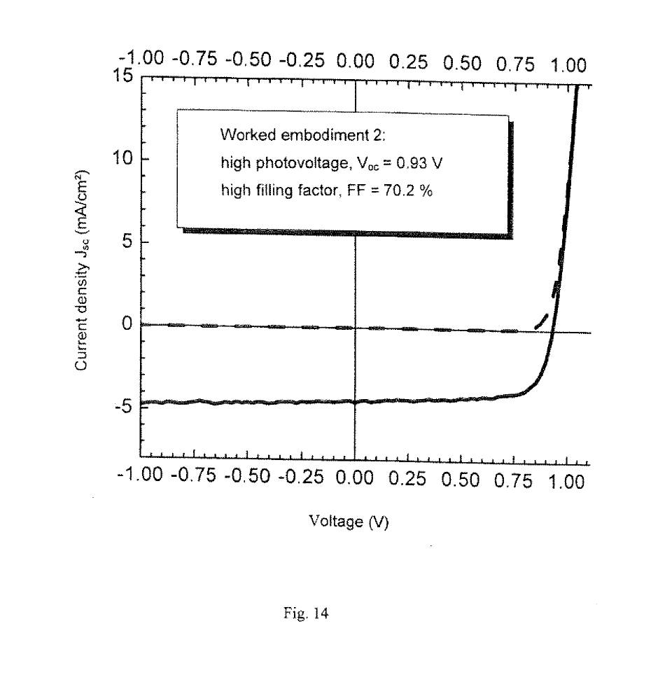

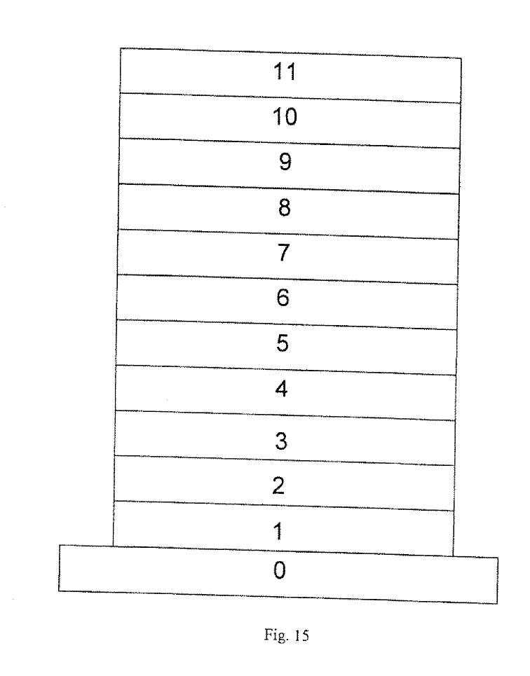

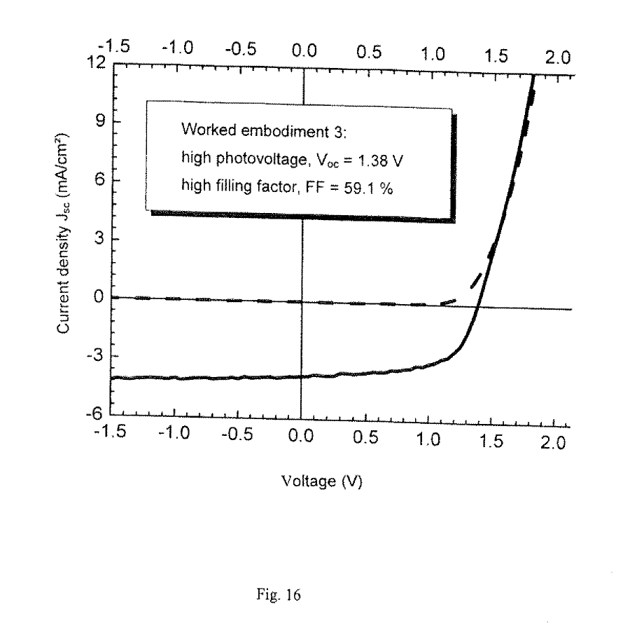

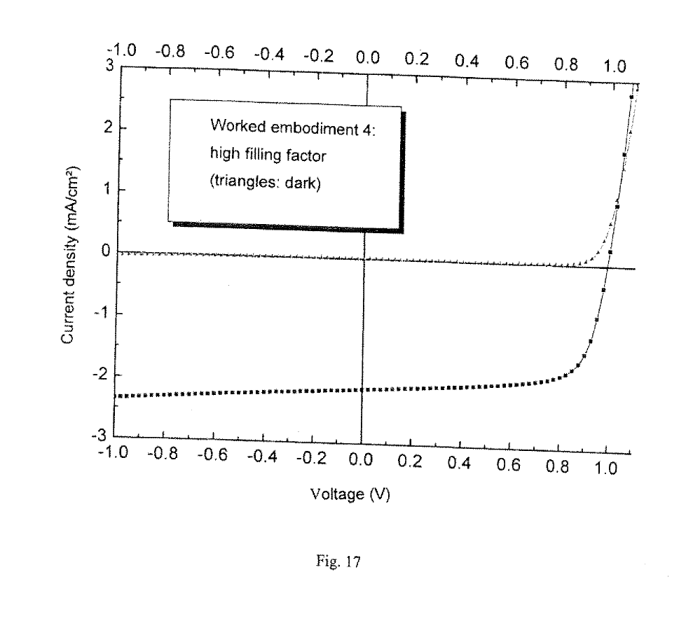

### EXAMPLES

### Synthesis Example 1

8,9-dibutyl-7,10-diphenyl fluoranthene: 3.56 g acecyclone (10 mmol), the same amount of 5-decin and 20 mL xylene were heated for 16 h in a sealed ampoule to 250° C. After all the volatile components had been removed by distillation, the residue was extracted from a layer of silica gel K60 with pentane. 2.91 g (6.24 mmol, 62% of theory) of a slightly yellowish solid were obtained. C36H34 Mw=466.66 g/mol. Elemental analysis: C, 92.22%; (adj. 92.66%), H, 7.42%; (adj. 7.34%).

ESI-MS (0.5 mM NH4COOH, +10 V): 467.3 (100) [M+H+], 950.6 (80) [2M+NH4+]. 1H-NMR (500 MHz, CDCl3): 7.61 (d, 3J=7.8 Hz, 1H), 7.60-7.52 (m, 3H), 7.48-7.46 (m, 2H), 6.26 (d, 33-6.8 Hz, 1H), 2.55 (t, 3J=8.4 Hz, 2H), 1.47 (quin., 3J=7.3 Hz, 3J=8.4 Hz, 2H), 1.21 (sex., 33-7.4 Hz, 3J=7.3 Hz, 2H), 0.77 (t, 3J=7.4 Hz, 3H). 13C-NMR (125 MHz, CDCl3): 140.7, 138.8, 137.9, 137.0, 135.2, 132.8, 129.4, 128.8, 127.5, 127.3, 125.8, 122.4, 33.6. 29.8, 23.2. 13.6.

### Synthesis Example 2

2,3,10,11-tertabutyl-1,4,9,12-tetraphenyl-di-indeno[cd:lm]perylene; 3.8 g iron(III) chloride in 6 mL nitromethane were added drop-wise to a deoxygenated solution of 0.933 g 8,9-dibutyl-7,10-diphenyl fluoranthene in 40 mL dichloromethane and then stirred for 5 min. Nitrogen was introduced constantly throughout. After the addition of 60 mL methanol, the mixture was filtered, and the solid was washed with methanol until the wash solution was colourless. The product was obtained in an amount of 0.867 g (1.87 mmol, 92% of theory) as a purple powder. C36H34 Mw=926.30 g/mol. Elemental analysis: C, 92.18%; (adj. 93.06%), H, 6.95%; (adj. 6.94%).

ESI-MS (0.5 mM NH4COOH, +10 V): 929.5 (100) [M+H+], 872.5 (23) [M+H+−C4H9]. 1H-NMR (500 MHz, CDCl3): 7.66 (d, 3J=7.7 Hz, 1H), 7.57-7.51 (m, 3H), 7.44-7.43 (m, 2H), 6.14 (d, 33-7.7 Hz, 1H), 2.49 (t, 3J=8.4 Hz, 2H), 1.45 (quin., 3J=8.4 Hz, 3J=7.6 Hz, 2H), 1.18 (sex., 3J=7.6 Hz, 3J=7.3 Hz, 2H), 0.74 (t, 3J=7.3 Hz, 3H). 13C-NMR (125 MHz, CDCl3): 140.5, 138.9, 138.0, 136.9, 135.3, 133.9, 129.9, 129.4, 128.7, 127.3, 124.9, 123.2, 121.4, 33.6, 29.7, 23.2, 13.6.

### Worked Embodiment 1

(The figures in the text refer to Illustration 11)

Documentation of an organic solar cell with a di-indenoperylene derivative (more precisely: dibenzoperiflanthene as a preferred example) as the absorber material using p-doped charge carrier transport layers. The objective here was to obtain a combination of a high photoelectric current and high photovoltage.

A sample was produced on glass (0), with a transparent earthing electrode of tin-doped indium oxide (ITO, 1), with a 1-nm-thick layer of a p-dopant or acceptor material, such as NDP9 (Novafed AG) (2), followed by a 25-nm-thick layer of N,N′-diphenyl-N,N′-bis(4′-(N,N-bis(naphth-1-yl)-amino)-biphenyl-4-yl)-benzidine (Di-NPD), p-doped with 5% of a p-dopant, such as NDP9, (3). The light-absorbing layers were applied on top: 6 nm dibenzoperiflanthene (4), 30 nm mixture of dibenzoperiflanthene with C60 (mixing ratio 2:3) (5), 35 nm C60 (6), followed by an exciton-blocker layer of 6 nm 4,7-diphenyl-1,10-phenanthroline (BPhen) (7) and 100 nm aluminium as the back contact (8).

In characterising the samples (the characteristic curves are shown in Ill. 12), it is noticeable that even without the absorber ZnPc, which is otherwise standard, a high photoelectric current of 8.08 mA/cm² can be achieved. The conclusion to be drawn from this is that C60 and dibenzoperiflanthene complement each other in their absorption characteristics and do not withdraw any photons from each other. A filling factor of 43.1% shows that the energy levels are not yet adapted optimally to one another, though the focus in this sample was on the photoelectric current. The high open-circuit voltage of 0.905V is almost twice as high as the voltage of conventional ZnPc:C60 systems, which indicates a favourable position of the energy levels between the absorber materials. All in all therefore, it is possible, by using di-indenoperylene in a simple cell structure, to achieve a notable efficiency of 3.15%, which is higher than the efficiencies of comparable C60:ZnPc solar cells (typical values here are 2-2.5%, see K. Walzer et al., Chemical Reviews 107(4), 1233-1271 (2007); C. Falkenberg et al., Journal of Applied Physics 104, 034506 (2008)). It was possible to achieve this figure here without absorption at wavelengths above approx. 650 nm, so that higher values can be expected if suitable red absorbers are added.

### Worked Embodiment 2

(The figures in the text refer to illustration 13)

Documentation of an organic solar cell with a di-indenoperylene derivative (more precisely: dibenzoperiflanthene) as the absorber material. The objective here was to obtain a combination of a high filling factor and high photovoltage.

A sample was produced on glass (0), with a transparent earthing electrode of tin-doped indium oxide (ITO, 1), with a 1-nm-thick layer of a p-dopant or acceptor material, such as NDP9 (Novaled AG) (2), followed by a 25-nm-thick layer of N,N′-diphenyl-N,N′-bis(4′-(N,N-bis(naphth-1-yl)-amino)-biphenyl-4-yl)-benzidine (Di-NPD), p-doped with 5% of a p-dopant, such as NDP9, (3). The light-absorbing layers were applied on top: 20 nm dibenzoperiflanthene (4), 35 nm C60 (5), followed by an exciton-blocker layer of 6 nm 4,7-diphenyl-1,10-phenanthroline (BPhen) (6) and 100 nm aluminium as the back contact (7).

The characteristic curve is shown in Illustration 14. The sample has an open-circuit voltage VOC=0.93V, a photoelectric current of ISC=4.54 mA/cm² and a very high filling factor of 70.2%, which leads to a high efficiency of 2.96%. This provides the evidence that even extremely high filling factors can be obtained by a targeted choice of the layer structure, which is a great advantage for applications in tandem cells or multiple cells.

### Worked Embodiment 3

(The figures in the text refer to Illustration 15)

Documentation of an organic solar cell with a di-indenoperylene derivative (more precisely: dibenzoperiflanthene) as the absorber material in a multiple cell (here: a tandem cell, consisting of two subcells). The aim in this context was to demonstrate in principle that C60, ZnPc and di-indenoperylenes can be combined in a cell structure and that a combination of a high voltage and a high filling factor can be achieved.

A sample was produced on glass (0), with a transparent earthing electrode of tin-doped indium oxide (ITO, 1), with a 1-nm-thick layer (of a p-dopant or acceptor material, such as NDP9 (Novaled AG) (2), followed by a 25-nm-thick layer of N,N′-diphenyl-N,N′-bis(4′-(N,N-bis(naphth-1-yl)-amino)-biphenyl-4-yl)-benzidine (Di-NPD), p-doped with 5% of a p-dopant, such as NDP9, (3). That was followed by the absorber layer of the first subcell: 25 nm ZnPc:C60 (ratio 1:1) (4). After that, a “conversion contact” was used to obtain an efficient, low-loss recombination of 5 nm C60 (n-doped with an n-dopant, such as NDN1, Novaled AG, Dresden) (5) and 10 nm p-doped di-NPD (doped with 5% NDP9) (6). That was followed by a layer of 5 nm 4,4′-bis-(N,N-diphenylamino)-quaterphenyl (4P-TPD) (7) for a barrier-free charge carrier transport to the conversion contact. The second subcell consisted of 25 nm dibenzoperiflanthene (8), 30 nm C60 (9), followed by an exciton-blocker layer of 6 nm 4,7-diphenyl-1,10-phenanthroline (BPhen) (10) and 100 nm aluminium as the back contact (11).

The characteristic curve is shown in Illustration 16. This tandem solar cell has a high filling factor of FF=59.1%. The photoelectric current is still relatively low, at ISC=3.25 mA/cm², which is due to the fact that no optimisation has been performed yet: in tandem cells the cell with the lower photoelectric current always limits the current of the overall cell, so that the two subcells have to be matched to one another optimally. All in all, embodiment 3 is a successful example of a tandem cell, since the photovoltage, at 1.38V, corresponds approximately to the sum of the voltages of single cells (typical C60:ZnPc—single cell: VOC=0.5V; solar cells from embodiments 1 and 2 approx. VOC=0.9V; the sum of the two subcells is thus approx. 1.4V, which is approximately reached by the tandem cell). As a result, with this non-optimised application, an efficiency of 3.25% was achieved.

### Worked Embodiment 4

The figures in the text refer to Illustration 8.

Documentation of an organic solar cell with a di-indenoperylene derivative (more precisely: 2,3,10,11-tertabutyl-1,4,9,12-tetraphenyl-di-indeno[cd:lm]perylene as the absorber material. The aim here was to achieve high filling factors and open-circuit voltages in a single cell without using a bulk heterojunction (mixed layer).

A sample was produced on glass (0), with a transparent earthing electrode of tin-doped indium oxide (ITO, 1), a 25-nm-thick absorber and electron transport layer of C60 (2), a 25-nm-thick layer of a di-indenoperylene derivative (more precisely: 2,3,10,11-tertabutyl-1,4,9,12-tetraphenyl-di-indeno[cd:lm]perylene, already described above in synthesis example 2) (3), followed by a 40-nm-thick layer of the hole-transport material BPAPF (9,9-bis[4-(N,N-bis-biphenyl-4-yl-amino)phenyl]-9H-fluorene), which is heavily p-doped with 20% by weight of a p-dopant, such as NDP9 (Novaled AG, Dresden) (4), followed by 10 nm ZnPc, p-doped with 2.5% by weight (5), followed by a 40-nm-thick layer of gold as the back electrode (6).

The characteristic curve is shown in Illustration 17. In charactering the cell, it is noticeable that by using hole-transport materials which are suitable from the energy point of view, combined with heavy p-doping, an extremely high filling factor of more than 69% is obtained. Filling factors on this level are not otherwise reported for organic solar cells. The filling factor and voltage (0.99 V) show that the use of dedicated charge carrier transport layers and dopants is of decisive importance. This makes it possible to adjust the energy levels precisely and thus to reduce energy barriers considerably. Only in this way can both high photovoltages and high filling factors be achieved, while keeping the series resistance low, which is necessary for efficient solar cells.

The features of the invention disclosed in the claims, the description and the drawings can be essential to implementing the invention in its various embodiments both individually and in any combination.

1. An organic photoactive component comprising a plurality of layers, wherein at least one of the layers comprises at least one di-indeno[1,2,3-cd:1′,2′,3′-lm]perylene compound of the general formula: 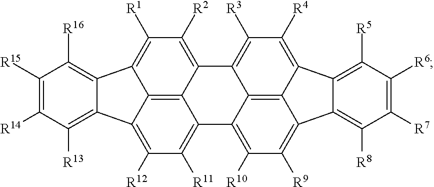
wherein each R¹-R¹⁶ is independently selected from hydrogen, halogen, C₁-C₂₀-alkyl, C₁-C₂₀-heteroalkyl, C₆-C₂₀-aryl, C₆-C₂₀-heteroaryl, carbocycle, heterocycle, or a carbocyclic or heterocyclic ring comprising two adjacent radicals selected from R¹-R¹⁶, wherein the C₁-C₂₀-alkyl, C₁-C₂₀-heteroalkyl, C₆-C₂₀-aryl, C₆-C₂₀-heteroaryl, carbocycle, heterocycle, carbocyclic ring, or heterocyclic ring is unsaturated or saturated, and substituted or unsubstituted.

2. The organic photoactive component as claimed in claim 1, wherein the photoactive component is a tandem solar cell comprising at least two electrodes and at least two layers arranged between the electrodes, each of which contains at least one layer with organic materials, wherein between the at least two layers arranged between the electrodes and each containing at least one layer with organic materials there is arranged at least one further layer consisting of organic, inorganic, or a combination of organic or inorganic materials, wherein the further layer comprises a conversion contact that recombines electrons and holes.

3. The organic photoactive component as claimed in claim 1, wherein the photoactive component is a triple solar cell comprising at least two electrodes and at least three layers arranged between the electrodes, each of which contains at least one layer with organic materials, wherein between the at least three layers arranged between the electrodes and each containing at least one layer with organic materials there is arranged at least one further layer comprising organic, inorganic, or a combination of organic or inorganic materials, wherein the further layer comprises a conversion contact and serves to recombine electrons and holes.

4. The organic photoactive component as claimed in claim 1, wherein the photoactive component is a multiple solar cell comprising a stack of plural solar cells.

5. The organic photoactive component as claimed in claim 1, wherein the photoactive component comprises at least one antidiffusion layer of at least one metal.

6. The organic photoactive component as claimed in claim 1, wherein the photoactive component comprises at least one thin metal layer consisting of a metal or a combination of more than one metal.

7. The organic photoactive component as claimed in claim 1, wherein the photoactive component comprises conversion contacts comprising at least one thin metal layer, at least one inorganic material, or at least one organic material.

8. The organic photoactive component as claimed in claim 1, wherein the organic photoactive component is arranged on a substrate.

9. The organic photoactive component as claimed in claim 8, wherein the organic photoactive component comprises an electric earth contact arranged on the substrate.

10. The organic photoactive component as claimed in claim 1, wherein the organic photoactive component comprises materials that conduct positive charges (holes).

11. The organic photoactive component as claimed in claim 1, wherein the organic photoactive component comprises materials that conduct negative charges (electrons).

12. The organic photoactive component as claimed in claim 1, wherein the component comprises p-dopants, which serve as acceptors.

13. The organic photoactive component as claimed in claim 1, wherein the component comprises n-dopants, which serve as donors.

14. The organic photoactive component as claimed in claim 1, wherein the component comprises at least one sequence of layers of heavily doped materials, wherein the at least one sequence of layers comprises at least one p-doped and at least one n-doped material, and serves as a charge carrier conversion contact.

15. The organic photoactive component as claimed in claim 1, wherein the organic photoactive component comprises at least one active layer comprising one or more materials which absorb photons.

16. The organic photoactive component as claimed in claim 1, wherein the organic photoactive component comprises an active layer comprising a plurality of materials which absorb photons, and wherein the plurality of materials are arranged in a mixed layer.

17. The organic photoactive component as claimed in claim 1, wherein the organic photoactive component comprises materials which serve as an exciton-blocker layer, wherein the exciton-blocker layer prevents excitons from reaching the electrode.

18. The organic photoactive component as claimed in claim 1, wherein the organic photoactive component encapsulated by one or more materials.

19. The organic photoactive component as claimed in claim 1, wherein the organic photoactive component comprises one or more covering layers for light coupling.

20. The organic photoactive component as claimed in claim 19, wherein the one or more covering layers consist of TiO₂ or SiO₂.

21. The organic photoactive component as claimed in claim 1, wherein the organic photoactive component or at least one part thereof is formed by thermal vaporisation or other thermal processes.

22. The organic photoactive component as claimed in claim 1, wherein the organic photoactive component or at least one part thereof is formed by rotation coating/spin-coating, dip-coating, drop-casting, doctor-blading, chemical vapour phase deposition (CVPD), organic vapour phase deposition (OVPD), electrodeposition, or other chemical, electrochemical or wet-chemical processes.

23. The organic photoactive component as claimed in claim 1, wherein the organic photoactive component or at least one part thereof is formed by screen printing, offset printing, inkjet printing, or other printing-based processes.

24. The organic photoactive component as claimed in claim 1, wherein that the organic photoactive component or at least one part thereof is formed by magnetron sputtering or other processes based on cathode sputtering.

25. The organic photoactive component as claimed in claim 1, wherein the organic photoactive component or at least one part thereof is formed by molecular beam epitaxy or comparable processes.

26. The organic photoactive component as claimed in claim 1, wherein the organic photoactive component or at least one part thereof is formed by a roll-to-roll process or comparable processes.

27. The organic photoactive component as claimed in claim 1, wherein the organic photoactive component or at least one part thereof is formed by laminating on a foil or comparable processes.

28. The organic photoactive component as claimed in claim 1, wherein the organic photoactive component or at least one part thereof is formed by self-assembled monolayers or comparable processes.

29. The organic photoactive component as claimed in claim 1, wherein the organic photoactive component or at least one part thereof is formed in the inverse order.

30. The organic photoactive component as claimed in claim 1, wherein the component comprises a layer structure comprising p-type transport materials, intrinsic materials, metals, and n-type transport materials together.

31. An organic solar cell comprising an organic photoactive component comprising a plurality of layers, wherein at least one of the layers comprises at least one di-indeno[1,2,3-cd:1′,2′,3′-lm]perylene compound of the general formula: 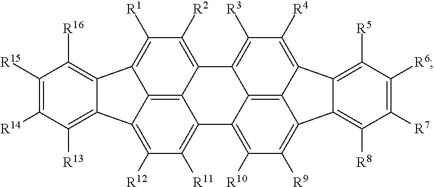
wherein each R¹-R¹⁶ is independently selected from hydrogen, halogen, C₁-C₂₀-alkyl, C₁-C₂₀-heteroalkyl, C₆-C₂₀-heteroaryl, carbocycle heterocycle, or a carbocyclic or heterocyclic ring comprising two adjacent radicals selected from R¹-R¹⁶, wherein the C₁-C₂₀-alkyl, C₁-C₂₀-heteroalkyl, C₆-C₂₀-aryl, C₆-C₂₀-heteroaryl, carbocycle, heterocycle, carbocyclic ring, and heterocyclic ring is unsaturated or saturated, and substituted or unsubstituted.

32. A photodetector comprising an organic photoactive component comprising a plurality of layers, wherein at least one of the layers comprises at least one di-indeno[1,2,3-cd:1′,2′,3′-lm]perylene compound of the general formula: 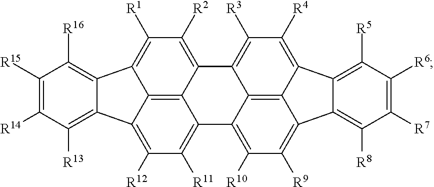
wherein each R¹-R¹⁶ is independently selected from hydrogen, halogen, C₁-C₂₀-alkyl, C₁-C₂₀-heteroalkyl, C₆-C₂₀-aryl, C₆-C₂₀-heteroaryl, carbocycle, heterocycle, or a carbocyclic or heterocyclic ring comprising two adjacent radicals selected from R¹-R¹⁶, wherein the C₁-C₂₀-alkyl, C₁-C₂₀-heteroalkyl, C₆-C₂₀-aryl, C₆-C₂₀-heteroaryl, carbocycle heterocycle, carbocyclic ring, and heterocyclic ring is unsaturated or saturated, and substituted or unsubstituted.

33. The organic photoactive component as claimed in claim 1, wherein the C₁-C₂₀-alkyl, C₁-C₂₀-heteroalkyl, C₆-C₂₀-aryl, C₆-C₂₀-heteroaryl, carbocycle, heterocycle, carbocyclic ring, or heterocyclic ring comprise at least one atom selected from the group consisting of N, O, S, Si, and Se.

34. The organic photoactive component as claimed in claim 5, wherein the at least one metal or transition metal is Ti, Pd, Cr, or a combination thereof.

35. The organic photoactive component as claimed in claim 6, wherein the at least one thin metal layer comprises an electric contact of the element aluminium, silver, gold, ytterbium, chromium, nickel, magnesium, iron, or a combination thereof.

36. The organic photoactive component as claimed in claim 7, wherein the at least one inorganic material comprises nanocrystals comprising clusters of one or more metal or inorganic material, wherein the clusters have an average diameter of less than 100 nm.

37. The organic photoactive component as claimed in claim 7, wherein the at least one organic material comprises doped or undoped molecules or polymers.

38. The organic photoactive component as claimed in claim 8, wherein the substrate comprises glass, aluminium foil, steel, textile material, plastic film, or a combination thereof.

39. The organic photoactive component as claimed in claim 12, wherein the p-dopants are arranged in a hole transport layer (HTL).

40. The organic photoactive component as claimed in claim 13, wherein the n-dopants are arranged in an electron transport layer (ETL).

41. The organic photoactive component as claimed in claim 30, wherein the component comprises a “p-i-n” structure.

42. The organic photoactive component as claimed in claim 30, wherein the component comprises a “p-i-i” structure.

43. The organic photoactive component as claimed in claim 30, wherein the component comprises an “m-i-p” structure.
